(19) United States
(12) Patent Application Publication
(10) Pub. No.: US 2024/0290612 A1
(43) Pub. Date: Aug. 29, 2024

(54) CONFORMAL AND SELECTIVE SIN DEPOSITION

(71) Applicant: Applied Materials, Inc., Santa Clara, CA (US)

(72) Inventors: Zeqing SHEN, San Jose, CA (US); Supriya GHOSH, San Jose, CA (US); Susmit Singha ROY, Campbell, CA (US); Abhijit Basu MALLICK, Fremont, CA (US); Nitin K. INGLE, San Jose, CA (US)

(21) Appl. No.: 18/409,549

(22) Filed: Jan. 10, 2024

Related U.S. Application Data
(60) Provisional application No. 63/486,782, filed on Feb. 24, 2023.

(51) Int. Cl. H01L 21/02; C23C 16/04; C23C 16/24; C23C 16/56

(52) U.S. Cl. CPC H01L 21/0217; C23C 16/04; C23C 16/24; C23C 16/56; H01L 21/02211; H01L 21/02247; H01L 21/02271

(57) ABSTRACT

The present disclosure generally relates to methods for forming silicon nitride film layers on substrates. In an embodiment, the method includes positioning a substrate having at least one feature thereon in a process chamber, depositing a first silicon film layer on a non-silicon oxide surface of the substrate for a time duration of about 1 to about minutes, nitriding the first silicon film layer to form a first silicon nitride film layer on the substrate, selectively depositing a second silicon film layer on the first silicon nitride film layer, and nitriding the second silicon film layer to form a second silicon nitride film layer disposed directly on the first silicon nitride film layer.

### CROSS-REFERENCE TO RELATED APPLICATIONS

This application claims benefit of U.S. provisional patent application Ser. No. 63/486,782, filed Feb. 24, 2023, which is herein incorporated by reference.

### BACKGROUND

### Field

Embodiments of the present disclosure generally relate to manufacture of semiconductor components and devices. More specifically, embodiments described herein provide methods for forming silicon nitride film layers on a semiconductor surface.

### Description of the Related Art

Silicon nitride has been extensively employed in the semiconductor and microelectronics industries. Silicon nitride films exhibit high temperature resistivity, high electrical resistivity, high conformality, and excellent etch-resistance. Thin silicon nitride films deposited by plasma enhanced chemical vapor deposition (PECVD) or conventional chemical vapor deposition (CVD) processes provide a number of functions, including serving as a charge storage layer, a stress liner, a masking layer, a dielectric layer, and a passivation layer.

Selective deposition of silicon nitride can be accomplished through the use of temporary mask structures. While temporary masks can be removed through either wet or dry processing, the use of wet chemicals is becoming less attractive due to particle control concerns and other challenges. The removal of masks using dry processes can alter the underlying layers, provoke charge-induced damage, and contaminate underlying layers. Thus, there is a need in the microelectronics and semiconductor industries for selective silicon nitride deposition methods that avoid the use of temporary mask structures.

### SUMMARY

Implementations described herein generally relate to method for selectively depositing a conformal silicon nitride film on a surface of a substrate. The method includes providing a substrate comprising a silicon oxide surface and a non-silicon oxide surface; depositing a first silicon film layer on the non-silicon oxide surface of the substrate for a time duration of about 1 to about 4 minutes; and nitriding the first silicon film layer to form a first silicon nitride film layer.

In another implementation, a method of selectively depositing a multi-layer conformal silicon nitride film on a surface of a substrate is provided. The method includes providing a substrate comprising a silicon oxide surface and a non-silicon oxide surface; selectively depositing a first silicon film layer on the non-silicon oxide surface of the substrate for a time duration of about 1 to 4 minutes; nitriding the first silicon film layer to form a first silicon nitride film layer; selectively depositing a subsequent silicon film layer on the first silicon nitride film layer; and nitriding the subsequent silicon film layer to form a multi-layer conformal silicon nitride film disposed directly on the non-silicon oxide surface of the substrate.

In yet another implementation, a method of selectively depositing a bulk conformal silicon nitride film on a surface of a substrate is provided. The method includes providing a substrate comprising a silicon oxide surface and a non-silicon oxide surface; performing a selective thermal CVD process to selectively deposit a silicon film layer on the non-silicon oxide surface of the substrate for a time duration of about 1 to 4 minutes; performing a plasma nitridation of the silicon film layer to form a silicon nitride film layer; performing a selective thermal CVD process to selectively deposit a silicon film layer on the silicon nitride film layer; performing a plasma nitridation of the silicon film layer to form a silicon nitride film layer; and repeating the selective thermal CVD and plasma nitridation processes from 10 to 1,000 times to provide a bulk conformal silicon nitride film.

### BRIEF DESCRIPTION OF THE DRAWINGS

So that the manner in which the above-recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 is a schematic illustration of a processing system that can be used for the practice of the method depicted in FIG. 2, according to certain embodiments of the present disclosure;

FIG. 2 depicts a flow diagram of a method for selectively depositing a conformal silicon nitride film on a surface of a substrate, according to certain embodiments of the present disclosure;

FIGS. 3A through 3F show cross-sectional views of a conformal silicon nitride film being formed by the method of FIG. 2, according to certain embodiments of the present disclosure; and

FIG. 4 is a graph depicting the deposition incubation delay of amorphous silicon deposition on oxidized silicon surfaces.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

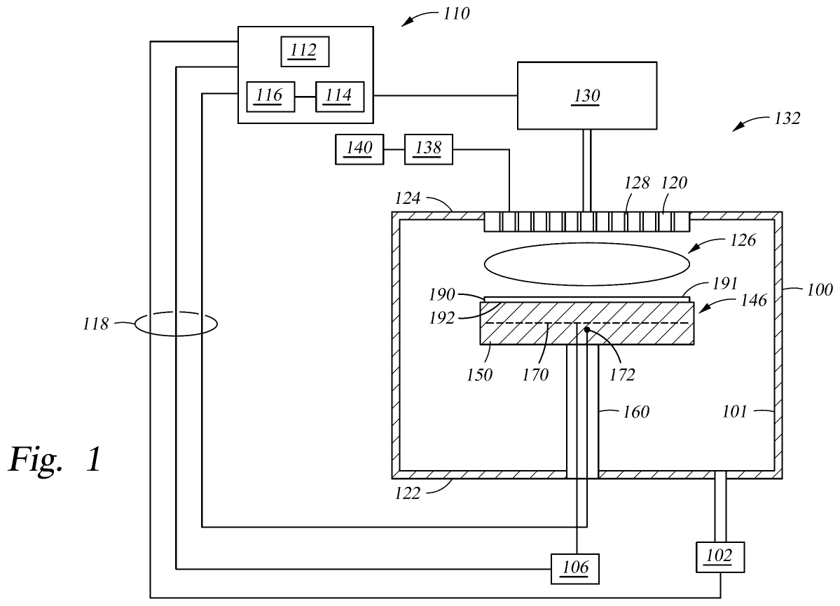

Embodiments of the present disclosure generally relate to apparatus and methods for the deposition of thin films to form structures on a substrate. Certain details are set forth in the following description and in FIGS. 1-4 to provide a thorough understanding of various implementations of the disclosure. Other details describing well-known methods and systems often associated with the deposition of thin films are not set forth in the following disclosure to avoid unnecessarily obscuring the description of the various implementations.

Many of the details, components and other features described herein are merely illustrative of particular implementations. Accordingly, other implementations can have other details, components, and features without departing from the spirit or scope of the present disclosure. In addition, further implementations of the disclosure can be practiced without several of the details described below.

Implementations described herein will be described below in reference to a PECVD process that can be carried out using any suitable thin film deposition system. Examples of suitable systems include the Precision™ systems, commercially available from Applied Materials, Inc., of Santa Clara, Calif. Other tools capable of performing PECVD processes may also be adapted to benefit from the implementations described herein. In addition, any system enabling the PECVD processes described herein can be used to advantage. The apparatus description described herein is illustrative and should not be construed or interpreted as limiting the scope of the implementations described herein.

FIG. 1 is a schematic illustration of an example substrate processing system 132 suitable for conducting a deposition process according to at least one embodiment. Suitable chambers may be obtained from Applied Materials, Inc. located in Santa Clara, Calif. It is to be understood that the system described below is an exemplary processing chamber and other chambers, including chambers from other manufacturers, may be used with or modified to accomplish embodiments of the present disclosure (e.g., method 200 described below). In some embodiments, the substrate processing system 132 may be configured to deposit thin films onto a substrate using a chemical vapor deposition process.

The substrate processing system 132 includes a process chamber 100 coupled to a gas panel 130 and a controller 110. The process chamber 100 generally includes a top wall 124, a sidewall 101 and a bottom wall 122 that define a processing volume 126. A substrate support assembly 146 is provided in the processing volume 126 of the process chamber 100. The substrate support assembly 146 generally includes an electrostatic chuck 150 supported by a stem 160. The electrostatic chuck 150 may be typically fabricated from aluminum, ceramic, and other suitable materials. The electrostatic chuck 150 may be moved in a vertical direction inside the process chamber 100 using a displacement mechanism (not shown).

A vacuum pump 102 is coupled to a port formed in the bottom wall 122 of the process chamber 100. The vacuum pump 102 is used to maintain a desired gas pressure in the process chamber 100. The vacuum pump 102 also evacuates post-processing gases and by-products of the process from the process chamber 100.

The substrate processing system 132 may further include additional equipment for controlling the chamber pressure, for example, valves (e.g., throttle valves and isolation valves) positioned between the process chamber 100 and the vacuum pump 102 to control the chamber pressure.

The gas distribution assembly 120 having a plurality of apertures 128 is disposed on the top of the process chamber 100 above the electrostatic chuck 150. The apertures 128 of the gas distribution assembly 120 are utilized to introduce process gases into the process chamber 100. The apertures 128 may have different sizes, number, distributions, shape, design, and diameters to facilitate the flow of the various process gases for different process requirements. The gas distribution assembly 120 is coupled to the gas panel 130 that allows various gases to supply to the processing volume 126 during processing. A plasma is formed from the process gas mixture exiting the gas distribution assembly 120 to enhance decomposition of the process gases resulting in the deposition of material on a surface 191 of the substrate 190. In some embodiments, the gas distribution assembly 120 is a concave or dome-shaped gas plate with the plurality of apertures 128 formed therethrough.

In one embodiment, the gas panel 130 includes a precursor gas such as a silicon-containing gas for forming films on a substrate 190 supported on the substrate support assembly 146. In some embodiments, the silicon-containing gas is silane (SiH₄), disilane (Si₂H₆), trisilane (Si₃H₈), or other higher order silanes, for example, but not limited to tetrasilane (Si₄H₁₀) or a combination thereof. Higher order silanes, such as tetrasilane (Si₄H₁₀) may not be in gaseous form, but rather in liquid form, but may be delivered to the process chamber 100 by use of a carrier gas such as argon or nitrogen gas.

The gas distribution assembly 120 may be coupled to a remote plasma source (not shown). The remote plasma source may be a capacitively coupled plasma source or an inductively coupled plasma source. The remote plasma source may also be coupled to a cleaning gas source for providing cleaning gases to the processing volume 126 formed inside the process chamber 100. In one embodiment, cleaning gases are provided through a central conduit formed axially through the top wall 124 of process chamber 100. In another embodiment, cleaning gases are provided through the same plurality of apertures 128, which direct the flow of the precursor gas. Example cleaning gases include oxygen-containing gases such as oxygen and/or ozone, as well as fluorine containing gases such as NF₃, or combinations thereof.

In addition to, or as an alternative to, the remote plasma source, the gas distribution assembly 120 is also coupled to a first or upper radio frequency (RF) power source 140. In other words, the gas distribution assembly 120 and the electrostatic chuck 150 may form a pair of spaced apart electrodes in the processing volume 126. The one or more RF power sources provide a bias potential through a matching network 138, which is optional, to the gas distribution assembly 120 to facilitate generation of plasma between the gas distribution assembly 120 and the electrostatic chuck 150. Alternatively, the RF power source 140 and the matching network 138 may be coupled to the gas distribution assembly 120, the electrostatic chuck 150, or coupled to both the gas distribution assembly 120 and the electrostatic chuck 150, or coupled to an antenna (not shown) disposed exterior to the process chamber 100. The first RF power source 140 facilitates maintenance or generation of plasma, such as a plasma generated from a cleaning gas. In one embodiment, the remote plasma source is omitted, and the cleaning gas may be ionized into a plasma in situ via the first RF power source 140. The substrate support assembly 146 may be coupled to a second or lower RF power source (not shown). In some implementations, the RF power sources may produce power at a frequency of 350 KHz, 2 MHz, 13.56 MHZ, 27 MHz, 40 MHz, 60 MHz, 100 MHz, or 120 MHz. For example, first RF power source 140 may produce power at a frequency of about 13.56 MHz to about 120 MHz and the second RF power source may be a low frequency RF power source (for example, about 2 MHz to about 13.56 MHz). It is to be noted that other frequencies are also contemplated. In some implementations, the second RF power source may be a mixed frequency RF power source, providing both high frequency and low frequency power. Utilization of a dual frequency RF power source, particularly for the second RF power source, improves film deposition. In some examples, utilizing a second RF power source provides dual frequency powers. In some embodiments, a first frequency of, e.g., about 2 MHz to about 13.56 MHZ, improves the implantation of species into the deposited film, while a second frequency of, e.g., about 13.56 MHz to about 120 MHz, increases ionization and deposition rate.

One or both of the first RF power source 140 and the second RF power source can be utilized in creating or maintaining a plasma in the processing volume 126. For example, the second RF power source may be utilized during a silicon nitridation process and the first RF power source 140 may be utilized during a cleaning process (alone or in conjunction with the remote plasma source). In some nitridation processes, the first RF power source 140 is used in conjunction with the second RF power source. During a nitridation process, one or both of the first RF power source 140 and the second RF power source can provide a power of, e.g., about 100 Watts (W) to about 20,000 W in the processing volume 126 to facilitation ionization of a precursor gas. In some embodiments, at least one of the first RF power source 140 and the second RF power source are pulsed.

The substrate support assembly 146 can include a heater element 170, such as a resistive element, embedded therein. The heater element 170 is coupled to a power source 106 regulated by the controller 110 to control the heat generated by the heater element 170. The heater element 170 can be disposed within the substrate support assembly 146 and can be used to controllably heat the substrate support assembly 146 and the substrate 190 positioned on the upper surface of the electrostatic chuck 150 to a predetermined temperature, for example between about 50° C. and about 600° C. A temperature sensor 172, such as a thermocouple, may be embedded in the electrostatic chuck 150 to monitor the temperature of the electrostatic chuck 150 in a conventional manner. The measured temperature is used by the controller 110 to control the power supplied to the heater element 170 to maintain the substrate at a desired temperature.

The controller 110 includes a central processing unit (CPU) 112, a memory 116, and a support circuit 114 utilized to control the process sequence and regulate the gas flows from the gas panel 130. The CPU 112 may be of any form of a general-purpose computer processor that may be used in an industrial setting. The software routines can be stored in the memory 116, such as random access memory, read only memory, floppy, or hard disk drive, or other form of digital storage. The support circuit 114 is conventionally coupled to the CPU 112 and may include cache, clock circuits, input/output systems, power supplies, and the like. Bi-directional communications between the controller 110 and the various components of the substrate processing system 132 are handled through numerous signal cables collectively referred to as signal buses 118, some of which are illustrated in FIG. 1.

Other deposition chambers may also benefit from the present disclosure and the parameters listed above may vary according to the particular deposition chamber used to form the amorphous silicon and conformal silicon nitride films. For example, other deposition chambers may have a larger or smaller volume, utilizing gas flow rates that are larger or smaller than the gas flow rates recited for deposition chambers available from Applied Materials, Inc. In addition, while a PECVD chamber is described above, it is contemplated that thermal CVD chambers may be utilized to in aspects of the present disclosure.

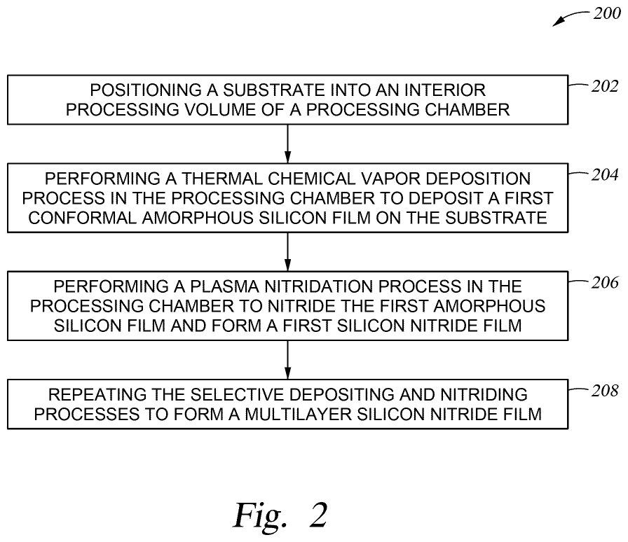

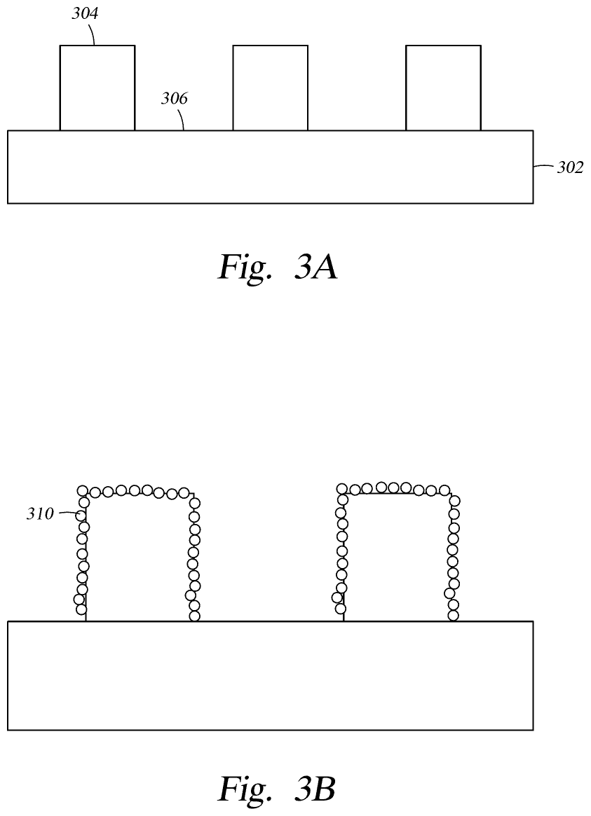

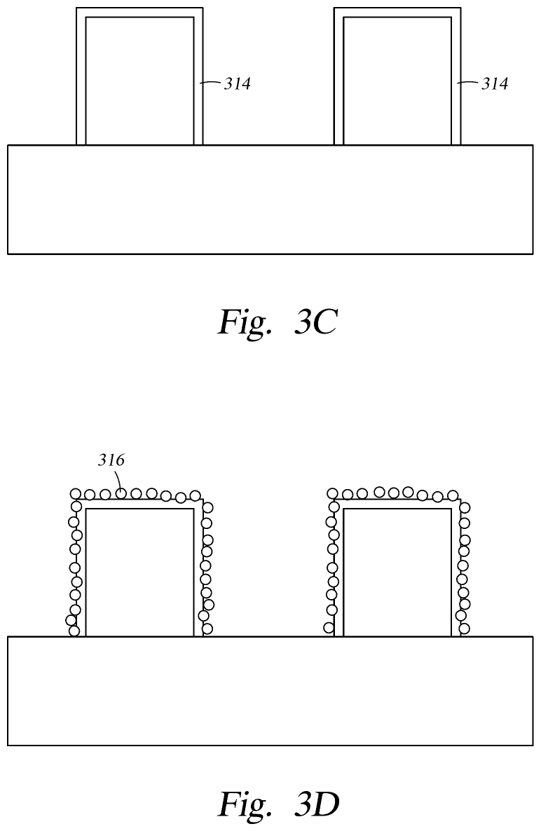

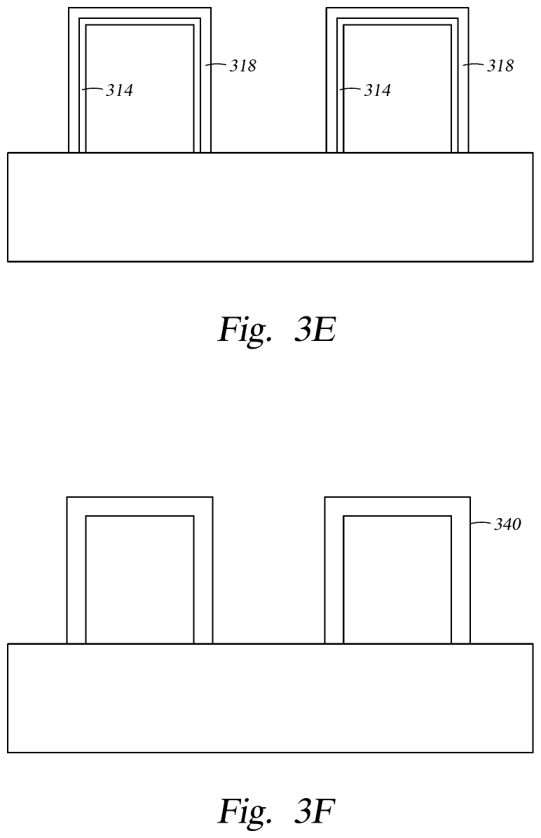

FIG. 2 is a flow diagram of an exemplary method 200 for forming a conformal silicon nitride film on a substrate using the process chamber 100 depicted in FIG. 1, according to certain embodiments described herein. In an embodiment, the method 200 begins at operation 202 by positioning a substrate, such as the substrate 302 shown in FIG. 3, in an interior processing volume 126 of the process chamber 100 for processing. In an embodiment, the substrate, e.g., substrate 302, is transferred into the process chamber 100 and onto the substrate support assembly 146 by any suitable means, such as by a substrate transfer port (not shown) on sidewall 101. The substrate support assembly 146 can be adjusted to a processing position by a lift actuator (not shown). The substrate 190 can be secured to the substrate support assembly 146 by the electrostatic chuck 150.

In the example shown in FIG. 3A, the substrate 302 has a silicon oxide surface 306 and a non-silicon oxide surface 304 (e.g., features). Examples of the non-silicon oxide surface include, but are not limited to, silicon, silicon nitride, and carbon. At operation 204, a first deposition process is performed on the substrate 302 in the process chamber 100 to selectively deposit a first amorphous silicon layer 310 on the substrate non-silicon oxide surface 304, as shown in FIG. 3B.

In an embodiment, the process chamber 100 can be a plasma enhanced chemical vapor deposition (PECVD) chamber as shown in FIG. 1. The first amorphous silicon layer 310 can be deposited on the substrate non-silicon oxide surface 304 using a thermal CVD process, for example, within a thermal CVD chamber or a PECVD chamber. It is noted that performing thermal processes in a PECVD chamber allow subsequent plasma-based processes to be performed on the substrate without the need for transferring a substrate to a different chamber, thereby improving throughput. The thermal CVD process to deposit the first amorphous silicon layer 310 includes flowing a silicon-containing precursor gas from the gas panel 130 into the interior processing volume 126 of the process chamber 100. In an embodiment, a silicon-containing precursor gas for forming the first amorphous silicon layer 310 can include silane, disilane, trisilane, tetrasilane, higher order silanes, or any combination thereof. In an embodiment, the thermal CVD process is performed between about 1 minute to about 4 minutes, and between about 2 minutes to about 3 minutes. The source-containing precursor gas is provided to the processing volume 126 through, e.g., the plurality of apertures 128 such that the source-containing precursor gas uniformly distributed in the processing volume 126.

The source-containing precursor gas can then be thermally decomposed in the interior processing volume 126 to deposit the first amorphous silicon layer 310 on the substrate non-silicon oxide surface 304. The first amorphous silicon layer 310 is selectively deposited on the substrate non-silicon oxide surface 304 over the substrate silicon oxide surface 306. The method takes advantage of the difference between silicon deposition nucleation times required on various surface compositions. Comparing the different nucleation rates of silicon on non-silicon oxide surface compared to that on a silicon oxide surface, it has been found that deposition by use of silane precursor based gases results in a longer nucleation time needed for silicon to start growing on silicon oxide surface than that on a non-silicon oxide surface. By employing a substrate that includes both silicon oxide and non-silicon oxide surfaces, the difference between silicon deposition nucleation time can be harnessed to selectively deposit amorphous silicon on a non-silicon oxide surface.

For deposition of the first amorphous silicon layer 310, the temperature of the substrate support assembly 146 in the process chamber 100 can be set to between about 50 degrees Celsius and about 600 degrees Celsius, e.g., between about 50 degrees Celsius and about 60 degrees Celsius when tetrasilane is used as the source-containing precursor gas or between about 400 degrees Celsius and about 600 degrees Celsius when lower order silanes are used as the source-containing precursor gas, and the pressure in the chamber may be between about 10 mTorr and about 760 Torr, e.g., about 300 Torr, during the thermal deposition process. The source-containing precursor gas flow rate is about 3 sccm to about 3000 sccm. The as-deposited amorphous silicon layer can have a thickness between about 2 Å and about 5,000 Å, such as, for example, about 2 Å to about 4000 Å, or about 2 Å to about 3000 Å, or about 2 Å to about 2000 Å, or about 2 Å to about 1000 Å, or about 2 Å to about 500 Å, or about 2 Å to about 250 Å, or about 5 Å to about 100 Å, or about 5 Å to about 50 Å, or about 5 Å to about 25 Å, or about 5 Å to about 10 Å.

At operation 206, an amorphous silicon nitridation process is performed on the substrate 302 in the process chamber 100 to treat the first amorphous silicon layer 310 and convert the first amorphous silicon layer 310 into a first silicon nitride layer 314. The nitration process is achieved by a plasma-based nitridation process. In an embodiment, plasma-based nitridation process includes performing a radical species nitridation in the processing volume 126 of the process chamber 100 using a plasma source (not shown).

The silicon nitridation performed using plasma processing can treat a layer of amorphous silicon to form a conformal layer of silicon nitride having a thickness that is from about 5 Å to about 60 Å. The thickness of the amorphous silicon layer is selected to achieve a predetermined conversion to a nitridated layer, for example, greater than 99 percent nitridation. As a result of controlled deposition of the amorphous silicon layer to within the limitation of the silicon nitridation process, the amorphous silicon layer is optimally converted in entirety to the conformal layer of silicon nitride. Should the amorphous silicon layer thickness exceed the silicon nitridation process limitations, the amorphous silicon layer beyond the limitation will remain amorphous silicon with a silicon nitride layer disposed on top.

The plasma-based nitridation process includes flowing a nitrogen-containing process gas, including but not limited to N₂, NH₃, hydrazine (N₂H₄), or combinations thereof, into the processing volume 126 for generation of a plasma. In some embodiments, the nitrogen-containing processes gases may be combined with argon or other inert gases. In other embodiments, the nitrogen-containing process gas further comprises hydrogen gas (H₂). The plasma can be generated by introducing process gas into the processing volume 126 and energizing the process gas to ignite the plasma. In general, the RF power generated to ignite and or maintain the plasma can be about 50 W to about 10 KW when processing a 300 mm substrate, however other power levels are also contemplated such as, for example, about 50 W to about 100 W, or such as about 1 kW to 1.5 KW, or about 1 KW to about 3 KW, or about 1 KW to about 5 KW, or about 2 kW to about 6 kW, or about 3 KW to about 8 kW, or about 5 KW to 10 kW.

When the plasma is ignited, radical nitrogen containing species formed from the nitrogen-containing process gas flow about the processing volume 126 and react with the first amorphous silicon layer 310. Such radical nitrogen containing species can include N and/or NH, for example, N· and/or NH· . . . During the nitridation process, radical nitrogen containing species saturate on the surface of the first amorphous silicon layer 310. The radical nitrogen-containing species react with and convert silicon atoms in the first amorphous silicon layer 310 into silicon nitride (SiN). Reaction between the radical nitrogen-containing species and silicon atoms in the first amorphous silicon layer 310 leads to the formation of the first silicon nitride layer 314, as shown in FIG. 3C.

In operation 206, the substrate 190 temperature is from about 100° C. to about 650° C., such as from about 150° C. to about 650° C.; and/or a pressure that is from about 0.025 Torr (25 millitorr (mTorr)) to about 5 Torr, such as from about 0.050 Torr (50 mTorr) to about 2 Torr. However, other temperatures and pressures are contemplated. The RF power may be controlled at between about 100 Watts and about 800 Watts, for example, about 400 Watts. The plasma forming gas, such as N₂ gas, may be supplied at between about 1000 sccm and about 5000 sccm, such as about 2000 sccm. In another embodiment, an NH₃ plasma forming gas may be supplied at between about 500 sccm and about 2000 sccm, such as about 1000 sccm.

At operation 208, operations 204 and 206 are repetitively performed on the substrate 302 in the process chamber 100 to selectively deposit a second amorphous silicon layer 316 on the first silicon nitride layer 314, as shown in FIG. 3D. The second amorphous silicon deposition process can be performed using the same conditions as outlined above for the deposition of the first amorphous silicon layer 310 by selectively depositing the second amorphous silicon on a non-silicon oxide surface, i.e. the resulting first silicon nitride layer 314. In some embodiments, conditions for deposition of the second amorphous silicon layer, including but not limited to temperature and pressure within the deposition chamber, can be different from the conditions used for the deposition of the first amorphous silicon layer 310. A second amorphous silicon nitridation process is performed to treat the second amorphous silicon layer 316 and convert the second amorphous silicon layer 316 into a second silicon nitride layer 318. The second amorphous silicon nitridation process can be performed using the same conditions as outlined above for the creation of the first amorphous silicon nitride layer. In some embodiments, conditions for creation of the second amorphous silicon nitride layer, including but not limited to temperature, pressure, RF power, and flow rate, can be different from the conditions used to create the first amorphous silicon nitride layer.

Deposition of an amorphous silicon layer and subsequent nitridation of the amorphous silicon layer can be repeated to provide a plurality of silicon nitride layers. In some embodiments, each layer of the silicon nitride layers fuses with the subsequent layer to form a single silicon nitride layer. In other embodiments, the plurality of silicon nitride layers are in a stacked arraignment, as shown in FIG. 3E. In some embodiments, each cycle of amorphous silicon layer deposition and subsequent nitridation provides a silicon nitride layer of approximately 10 angstroms in thickness. Deposition of an amorphous silicon layer and subsequent nitridation of the amorphous silicon layer can be repeated until the desired silicon nitride layer thickness is reached. Deposition of an amorphous silicon layer and subsequent nitridation of the amorphous silicon layer can be repeated any one of, less than, or greater than 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 110, 120, 130, 140, 150, 160, 170, 180, 190, 200, 300, 400, 500, 600, 700, 800, 900, and 1,000 times to produce the final nitridation layer 340 of FIG. 3F.

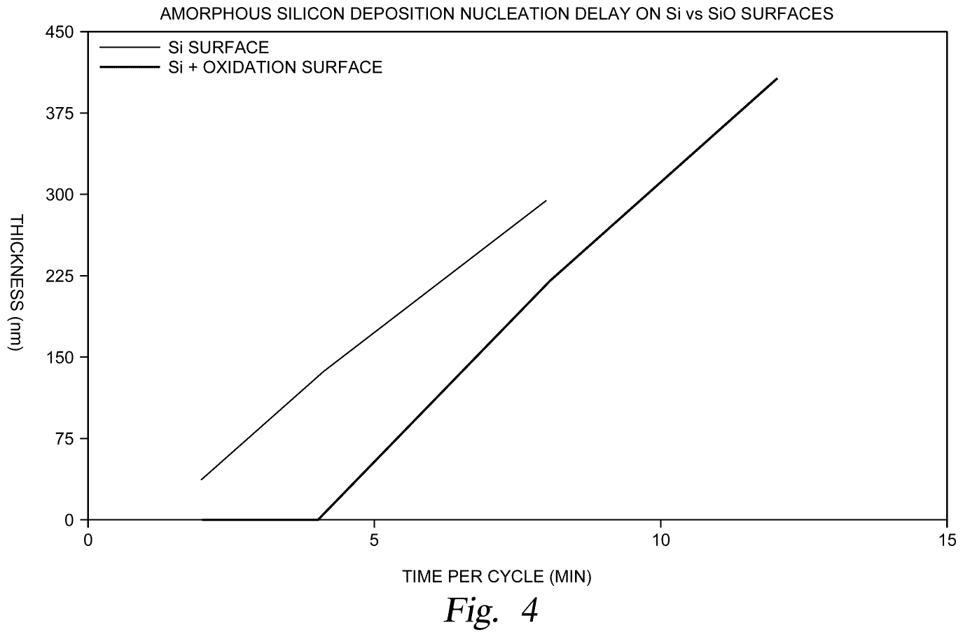

FIG. 4 shows the difference between silicon deposition nucleation rates on a silicon oxide surface and a non-silicon oxide surface, e.g., a silicon surface. The initial nucleation deposition rate of amorphous silica on a silicon oxide surface is zero, and this zero deposition rate increases after approximately four minutes. By contrast, the initial nucleation deposition rate of amorphous silicon on a silicon surface (i.e., a non-silicon oxide surface) is greater than zero. Deposition of amorphous silicon on a non-silicon oxide surface occurs while deposition of amorphous silicon on a silicon oxide surface is delayed. The difference between the initial nucleation deposition rates can be harnessed to selectively deposit amorphous silicon on a non-silicon oxide surface, such as on a silicon surface.

In summary, some benefits of some implementations of the present disclosure provide methods for achieving selectively deposition of conformal silicon nitride films. The conformal silicon nitride films may comprise a single silicon nitride layer or a plurality of silicon nitride layers. Using aspects described herein, in certain embodiments, it has been found that by using the amorphous silicon deposition and subsequent silicon nitridation processes disclosed herein, conformal silicon nitride layers can be built upon a surface of a substrate. In an embodiment, the silicon deposition and subsequent silicon nitridation processes disclosed herein may be performed in situ in the same process chamber 100, making transfers of the substrate and use of costly cluster systems unnecessary. Furthermore, because the deposition process utilized herein employ low cost silicon-precursor gases such as silane and disilane and low-cost nitrogen gases like nitrogen and ammonia, the total cost of silicon nitride deposition is less expensive than other deposition methods that employ higher-cost materials.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the present disclosure may be devised without departing from the basic scope thereof, and the scope thereof is determined by the claims that follow.

1. A method of selectively depositing a conformal silicon nitride film on a surface of a substrate, comprising:
providing a substrate comprising a silicon oxide surface and a non-silicon oxide surface;
depositing a first silicon film layer on the non-silicon oxide surface of the substrate for a time duration of about 1 to about 4 minutes; and
nitriding the first silicon film layer to form a first silicon nitride film layer.

2. The method of claim 1, further comprising depositing a second silicon film layer on the first silicon nitride film layer.

3. The method of claim 2, further comprising nitriding the second silicon film layer to form a second silicon nitride film layer.

4. The method of claim 1, wherein depositing the first silicon film layer comprises depositing the first silicon film layer by a CVD process.

5. The method of claim 4, wherein the CVD process uses a silane gas as a silicon source.

6. The method of claim 5, wherein the silane gas comprises SiH₄, Si₂H₆, Si₃H₈, Si₄H₁₀, or a combination thereof.

7. The method of claim 1, wherein the time duration is 2 to 3 minutes.

8. The method of claim 1, wherein nitriding the first silicon film layer comprises treating the first silicon film layer with a nitrogenous plasma comprising N₂, NH₃, N₂H₄, or any combination thereof.

9. The method of claim 1, wherein the non-silicon oxide surface is selected from the group consisting of silicon, silicon nitride, and carbon.

10. A method of selectively depositing a multi-layer conformal silicon nitride film on a surface of a substrate, comprising:
providing a substrate comprising a silicon oxide surface and a non-silicon oxide surface;
selectively depositing a first silicon film layer on the non-silicon oxide surface of the substrate for a time duration of about 1 to 4 minutes;
nitriding the first silicon film layer to form a first silicon nitride film layer;
selectively depositing a subsequent silicon film layer on the first silicon nitride film layer; and
nitriding the subsequent silicon film layer to form a multi-layer conformal silicon nitride film disposed directly on the non-silicon oxide surface of the substrate.

11. The method of claim 1, wherein depositing the first silicon film layer comprises depositing the first silicon film layer by a CVD process.

12. The method of claim 11, wherein the CVD process uses a silane gas as a silicon source.

13. The method of claim 12, wherein the silane gas comprises SiH₄, Si₂H₆, Si₃H₈, Si₄H₁₀, or a combination thereof.

14. The method of claim 10, wherein nitriding the first silicon film layer comprises treating the first silicon film layer with a nitrogenous plasma.

15. The method of claim 14, wherein the nitrogenous plasma comprises a source gas, wherein the source gas comprises N₂, NH₃, N₂H₄, or combinations thereof.

16. The method of claim 10, wherein the non-silicon oxide surface is selected from the group consisting of silicon, silicon nitride, and carbon.

17. A method of selectively depositing a bulk conformal silicon nitride film on a surface of a substrate, comprising:
providing a substrate comprising a silicon oxide surface and a non-silicon oxide surface;
performing a selective thermal CVD process to selectively deposit a silicon film layer on the non-silicon oxide surface of the substrate for a time duration of about 1 to 4 minutes;
performing a plasma nitridation of the silicon film layer to form a silicon nitride film layer;
performing a selective thermal CVD process to selectively deposit a silicon film layer on the silicon nitride film layer;
performing a plasma nitridation of the silicon film layer to form a silicon nitride film layer; and
repeating the selective thermal CVD and plasma nitridation processes from 10 to 1,000 times to provide a bulk conformal silicon nitride film.

18. The method of claim 17, wherein the selective CVD process uses a silane gas selected from the group consisting of SiH₄, Si₂H₆, Si₃H₈, Si₄H₁₀, or a combination thereof as a silicon source.

19. The method of claim 17, wherein the plasma nitridation process employs a nitrogenous source gas selected from the group consisting of N₂, NH₃, N₂H₄, or combinations thereof.

20. The method of claim 17, wherein the non-silicon oxide surface is selected from the group consisting of silicon, silicon nitride, and carbon.
